(19) United States
(12) Patent Application Publication
(10) Pub. No.: US 2015/0121684 A1
(43) Pub. Date: May 7, 2015

(54) Self contained breathing apparatus (SCBA) electronics system

(71) Applicant: HUDstar Systems, Inc., West Palm Beach, FL (US)

(72) Inventors: Tommi Lennart Kuutti, West Palm Beach, FL (US); Jeffrey Acton Barnitz, Boca Raton, FL (US); Clayton Joseph Emery, Davie, FL (US); Eugene Victor Horanoff, Jupiter, FL (US); Sam Shifron, Del Mar, CA (US)

(73) Assignee: HUDstar Systems, Inc., West Palm Beach, FL (US)

(21) Appl. No.: 14/214,392

(22) Filed: Mar. 14, 2014

Related U.S. Application Data
(60) Provisional application No. 61/799,858, filed on Mar. 15, 2013.

(51) Int. Cl. H05K 13/00

(52) U.S. Cl. CPC H05K 13/0023
USPC 29/592.1

(57) ABSTRACT

A self contained breathing apparatus electronics system that provides a method for maximizing battery life, estimating remaining battery life and condition, insuring reliable communications between modules, maintaining reliable real-time clock (RTC), minimizing piezo interference, minimizing effects of RFI and EMI on pressure measurement, retaining consistency in the motion detection circuitry due to sensitivity to temperature changes, and providing a thermal imaging camera in cooperation with either a HUD or POD mounted inside a SCBA facemask.

### PRIORITY CLAIM

In accordance with 37 C.F.R. 1.76, a claim of priority is included in an Application Data Sheet filed concurrently herewith. Accordingly, the present application is based upon and claims the priority date of U.S. Provisional Patent Application 61/799,858 filed Mar. 15, 2013 and entitled Self Contained Breathing Apparatus (SCBA) Electronics System, the contents of which is incorporated herein by reference.

### FIELD OF THE INVENTION

This invention relates generally to the breathing apparatus field and, in particular, to an improved battery powered self contained breathing apparatus (SCBA) Electronics System for use by firefighters and other rescue personnel capable of extending battery life and providing a Thermal Imaging Camera—Heads-Up Display (TIC-HUD) or Thermal Imaging Camera—Passive Optical Display (TIC-POD) inside a SCBA facemask.

### BACKGROUND OF THE INVENTION

Self contained breathing apparatus, or SCBA, is a device worn by firefighters and rescue personnel to provide breathable air in an immediate danger to life and health situation. A SCBA typically has four main components: a high-pressure tank, a pressure regulator, an inhalation connection and an electronics system, all affixed together and mounted onto a carrying frame. SCBA's are one of the most important items of personal protective equipment used by firefighters and rescue personal. SCBA's allow firefighters to enter hazardous environments to perform essential interior operations including offensive fire attacks, victim search, rescue and removal, ventilation, and overhaul. They are also used at non-fire incidents involving hazardous material and confined spaces where there is a threat of toxic fumes or an oxygen-deficient atmosphere. A SCBA may fall into one of two different categories: an open circuit or a closed circuit SCBA.

SCBA systems used in firefighting places an emphasis on quality of materials required for heat and flame resistance above that of manufacturing cost. SCBA systems tend to be expensive because of the exotic materials used to provide heat and flame resistance and, to a lesser extent, to reduce the weight penalty on the firefighter. In addition, modern SCBA's incorporate a PASS (Personal Alert Safety System) device or an ADSU (Automatic Distress Signal Unit) into their design. These units emit distinctive high pitched alarm tones to help locate firefighters in distress following automatic activation if movement on the part of the firefighter is not sensed for a certain length of time. In addition to the PASS and ADSU units, SCBA's have been equipped with thermal imaging cameras to aid with vision, a Black Box for data logging, microphones for in-mask firefighter to firefighter communication, and much more.

There have been several documented incidents where a SCBA failure may have been a contributing factor in the deaths of or injuries to firefighters. These incidents, coupled with a recognition of the importance of self contained breathing apparatus safety, prompted the U.S. Fire Administration to undertake various studies to address the many operational trends associated with SCBA failure incidents and to identify potential problems requiring correction or standardization. Equipment of such importance warrants close scrutiny. How much change is necessary and to what extent it will help a fire service must be asked. Standards and testing procedures have been changed over time to address problems that led to equipment failures and to ensure that SCBA's are more durable and reliable. As regular inspection, upgrade, and preventive maintenance will lessen the potential for catastrophic failures of a SCBA, standards for such were established in the National Fire Protection Association (NFPA) 1981 specification and NFPA 1982 specification, 2013 edition.

There have been several issues and operational failures that are frequently identified in SCBA maintenance and user training manuals and exercises. One of the most common is the failure to use the SCBA system correctly. Even with current emphasis on firefighter health and safety, and the expanding knowledge of the hazard posed by the products of combustion, some firefighters still fail to use SCBA during interior operations in smoke filled environments, especially during cases of salvage and overhaul. Injuries or even death can thus be avoided by continuing to educate firefighters about the risk involved from failure to use a SCBA. As a result, creating an easy to use, comfortable, and cost-efficient SCBA system is a very important consideration for manufacturers.

Another concern is hardware reliability, including battery failure. SCBA's are to be tested and certified according to the requirements set forth by the NFPA 1981 specification, entitled the Standard for Open Circuit Self Contained Breathing Apparatus. This ensures that SCBA's are extremely durable and rugged. If the SCBA is properly used and maintained by well-trained personnel, it should provide years of trouble-free service with little potential for hardware failure. However, battery failure is an all-to-common occurrence and the NFPA has required specific protocols, such as the PASS and ADSU (discussed above), to help prevent such failures. Lastly, some failures of the SCBA system may not directly result in death or injury, but may reduce efficiency and hamper firefighter performance. This type of failure is relatively common and most often attributable to operator error, physical abuse/neglect to the system, or inadequate preventive maintenance procedures. Examples include: difficult or slow donning of SCBA due to lack of familiarity or infrequent practice; free flowing regulators; O-rings blown out during cylinder changes; and improperly connected hoses or regulators. Below are some specific SCBA system failures not yet addressed.

On the average in the United States, most fire departments use their SCBA less than one-half hour per day. Thus for more than 23 hours per day, the SCBA is typically left dormant. When firefighters respond to a call time is of the essence, adrenaline is flowing, and tensions are high. With this fully understood, NFPA does not permit SCBA equipment to be equipped with an ON/OFF switch. Instead some automated detection means must be employed. Presently, most SCBA systems include a microcontroller that is programmed to monitor the air tank pressure during periods when the SCBA is inactive. With this the SCBA system can be made to turn on automatically within a few seconds after the air tank valve is opened and an increase in pressure is detected. Unfortunately, to save battery life, most SCBA systems program the microcontroller to enter a Sleep Mode function during periods of inactivity, typically scheduling it to wake up every few seconds to check air tank pressure. This method causes the Sleep Mode function to consume approximately 40% of the total SCBA battery life, which can lead to battery failure and possible malfunction during use, thereby compromising firefighter safety.

Additionally, under low voltage battery conditions the SCBA electronics operation can malfunction. NFPA electronics requirements demand that SCBA electronics determine the capacity of the SCBA battery power supply and report if it is insufficient for proper use. NFPA requires that the SCBA warn the firefighter of a low battery condition no later than when the batteries can provide just enough energy for the SCBA to function continuously for 2 hours in ‘Alarm Mode’. In order to maintain safe operation, it is important to be able to determine the condition or ‘health’ of the batteries, to be able to estimate the remaining battery life in ‘Alarm Mode’, and to provide a ‘Change Battery’ warning at the appropriate time. A test battery load current and battery load voltage measurement is employed to predict the remaining power reserves in the SCBA equipment. The battery test load current must be similar to the actual SCBA battery load. The traditional test for battery condition employs a fixed battery load resistor turned on and off by the circuit, while measuring the SCBA battery voltage change resulting from current draw. Using derived unit of electrical resistance law (ohm), an ohm value of the battery test load resistor must be selected to ensure that the low battery voltage current test load is similar to the actual SCBA load at that voltage. A fixed value battery load resistor with variable battery voltage allows for generation of a battery test load current at high voltage levels that can be unnecessarily excessive. Thus, a power conserving solution which employs a constant current battery test load where no power is wasted at high battery voltage levels would conserve SCBA battery life during battery load testing.

The most common electromagnetic interference (EMI) resistance circuit methods employ shielding, low source impedance and protection devices to mitigate the effects of EMI. The disadvantage of the low source impedance technique is that the amount of power required to protect the circuit increases with protection levels, therefore the lower the impedance of the circuit the greater the EMI protection level and power consumed. Again, battery consumption can be compromised. What is needed is a power conserving EMI circuit that changes the impedance of the circuit from low impedance high protection when the SCBA electronics is sleeping to high impedance low power when awake in order to conserve battery power.

NFPA requires a Black Box with SCBA for data logging, i.e. the SCBA electronics must record and time-stamp alarm conditions and certain other specified events. The data logs provide forensic information in the event of an accident occurring during operation of the SCBA. Clearly, having an accurately recorded time-stamp is important. Existing SCBA systems typically employ a real-time clock (RTC) to provide the time-stamp. The event data and the time-stamp are stored in non-volatile memory. Unfortunately, an RTC failure can cause the time-stamp to be lost, typically rendering the logged data useless for forensic purposes. Currently RTC failure experienced with a SCBA systems results in the time-stamp date being reverted to the RTC “default” date, which is not an accurate representation of the actual time of the event.

NFPA requires that a Personal Alert Safety System (PASS) device enters Pre-Alarm Mode if a firefighter is detected to be motionless for 20 seconds. The PASS piezo emitter must generate an NFPA specified sound in Pre-Alarm Mode. If the firefighter continues to remain motionless for an additional 12 seconds, the PASS must enter Alarm Mode and generate an NFPA specified universal alarm sound for the firefighter and perhaps more particularly for others, to hear continuously thereafter until the PASS piezo is turned OFF manually, indicating that the firefighter has depressed the Reset Button in response to the alert. Most SCBA manufacturers equip their PASS devices with an accelerometer to detect motion and include a piezo emitter and/or a volume acoustic speaker (VAS) in their PASS device housing. Presently, a problem/safety issue can occur when, under certain circumstances, vibrations generated by the piezo or speaker are transmitted through the PASS device housing causing interference with the operation of the accelerometer. Specifically, when the PASS enters Pre-Alarm Mode due to lack of movement for 20 seconds, the piezo commences emitting sound, which causes vibrations. These vibrations are transmitted through the housing and are detected by the accelerometer. The accelerometer sends a signal to the Microcontroller that it is detecting vibrations. The Microcontroller interprets the vibrations as movement by the firefighter, which turns OFF the piezo, and resets the 20-second clock. Unfortunately, this can lead to valuable rescue time being lost should the firefighter be in actual peril and, in a worst case scenario, can lead to possibly deadly consequences.

Thus, what is lacking in the prior art is a self contained breathing apparatus electronics system having sophisticated individual modules to alleviate the potential for such problems and maximizing battery life and providing a TIC-HUD or TIC-POD inside a SCBA facemask.

### SUMMARY OF THE INVENTION

A self contained breathing apparatus (SCBA) electronics system that provides a method for maximizing battery life, estimating remaining battery life and condition, insuring reliable communications between modules, maintaining reliable real-time clock (RTC), minimizing piezo interference, minimizing effects of RFI and EMI on pressure measurement, and remaining consistent in the motion detection circuitry due to sensitivity to temperature changes is provided.

Accordingly, it is an objective of the instant invention to provide a self contained breathing apparatus electronics system that supplies the operator with an indicator of the amount of air in the self contained breathing apparatus's air tank.

It is also an objective of the instant invention to provide a self contained breathing apparatus electronics system that monitors the movement of the operator and emits an alert if the operator goes without motion for a specified time.

It is another objective of the instant invention to provide a self contained breathing apparatus electronics system that logs alert conditions and ambient environmental conditions during operation. This SCBA system also logs a backup time stamp upon each power up and compares dates and time with the real-time clock (RTC).

It is a further objective of the instant invention to provide a self contained breathing apparatus electronics system that during operation presents visual and audio indicators to allow easier tracking of the self contained breathing apparatus in visually obscured environments. The SCBA also makes use of a thermal imaging camera (TIC) that will aid vision in dark and/or line-of-sight impaired conditions. A head mounted thermal imaging camera will naturally adjust to the orientation of the firefighters head showing an enhanced picture of obstacles and persons, whether they be other firefighters or merely individuals in need of assistance.

It is yet a further objective of the instant invention to provide a self contained breathing apparatus electronics system that amplifies the operator's voice to facilitate communications between rescue personnel while the operator is using breathing air.

It is a still further objective of the instant invention to provide a self contained breathing apparatus electronics system that is built to conform to the functional requirements of the NFPA 1981 specification and 1982 specification, 2013 edition. The SCBA of the instant invention will comply with power protection circuitry set forth in Underwriters Laboratories (UL) 913, 6^{th} edition.

It is an additional objective of the instant invention to provide a self contained breathing apparatus electronics system that includes an emergency locator transmitter, whereby when activated emits a signal that can be tracked using a matching tracking system.

It is a further objective of the instant invention to provide a self contained breathing apparatus electronics system that also includes an interface to an external radio. When the radio is connected, audio from the radio is routed to the voice amplification system and voice audio from the heads-up display microphone is routed to the radio transmitter.

It is a further objective of the instant invention to provide a self contained breathing apparatus electronics system having a method for maximizing battery life by having the electronics powered by two separate voltage regulators—a high current regulator for Active Mode operation and a low quiescent current regulator for Inactive (Sleep) Mode operation.

It is a further objective of the instant invention to provide a self contained breathing apparatus electronics system having a method for estimating remaining battery life and condition, where, the voltage of the batteries is measured in both unloaded and loaded states, using a temporary load proportional to the estimated maximum load of the SCBA electronics. The battery condition is determined such that, the unloaded voltage (VUL) and loaded voltage (VL) measurements are compared to an unloaded voltage threshold level (VTH-UL) and a loaded voltage threshold level (VTH-L), where the VTH-UL and VTH-L threshold voltages are determined empirically through measurement of the voltage decrease in the SCBA electronics during operation over time. This gives an estimate of the remaining life of the batteries when a threshold voltage is reached and if the measured voltage falls below either threshold level then the ‘change battery’ indicator is activated.

It is a further objective of the instant invention to provide a self contained breathing apparatus electronics system able to insure reliable communications between modules by implementing a derivative of the IEEE RS-485 communications bus in the circuit design for communication between the various SCBA Electronics Modules.

It is a further objective of the instant invention to provide a self contained breathing apparatus electronics system able to maintain a reliable RTC, by initializing upon power up a backup time-stamp that is maintained by the system clock, the Microcontroller's internal oscillator, which is separate from the RTC clock. The reliable real time clock is maintained by having the Microcontroller compare the date/time provided by the RTC to the most recent time-stamp from the most recently stored data log and, if the Microcontroller determines that the RTC has provided an unrealistic or invalid date/time indicative of RTC failure, then the backup time-stamp is used henceforth in its place

It is a further objective of the instant invention to provide a self contained breathing apparatus electronics system having a method for minimizing piezo and Voice Amplification System (VAS) Speaker interference in the Mobile Personal Alert Safety System PASS Module, by utilizing a software algorithm, which is tuned separately for each axis of movement on the XYZ accelerometer to attenuate high frequency vibrations, thereby allowing only low frequency motion to be detected resulting in less interference.

It is a further objective of the instant invention to provide a self contained breathing apparatus electronics system having a method for minimizing effects of electromagnetic interference (EMI) on pressure measurement by utilizing a software algorithm that checks for a constantly increasing air pressure over a period of time in order to verify that the pressure is valid prior to awakening the SCBA electronics.

Other objectives and advantages of this invention will become apparent from the following description taken in conjunction with any accompanying drawings wherein are set forth, by way of illustration and example, certain embodiments of this invention. Any drawings contained herein constitute a part of this specification and include exemplary embodiments of the present invention and illustrate various objects and features thereof.

### BRIEF DESCRIPTION OF THE FIGURES

FIG. 1 is diagram of the Self Contained Breathing Apparatus (SCBA) Electronics System of the instant invention;

FIG. 2 is diagram of the components of the Main SCBA Computer Module of the instant invention;

FIG. 3 is a diagram of the components of the Mobile Personal Alert Safety System (PASS) Module of the instant invention;

FIG. 4 is a diagram of the components of the Power Saving Pressure Transducer (PSPT) Module of the instant invention;

FIG. 5 is a diagram of the components of the Heads-Up Display (HUD) Module of the instant invention;

FIG. 6 is a diagram of the components of the Telemetry Transceiver (TT) Module of the instant invention;

FIGS. 7A-7B are a flowchart of the method for determining battery condition and estimating remaining battery life of the instant invention;

FIG. 8 is a schematic representation of an EMI resistance circuit of the prior art;

FIG. 9 is a schematic representation of an EMI resistance circuit of the instant invention;

FIG. 10 is a schematic representation of the common battery load test of the prior art

FIG. 11 is a schematic representation of the linear regulator battery load test of the instant invention;

FIG. 12 is a schematic representation of reverse battery protection of the prior art;

FIG. 13 is a schematic representation of reverse battery protection of the instant invention;

FIG. 14 is a block diagram of a wireless TIC-HUD with a see through reflector;

FIG. 15 is a block diagram of the Passive Optical Display (POD) with a see-through reflector.

### DETAILED DESCRIPTION OF THE INVENTION

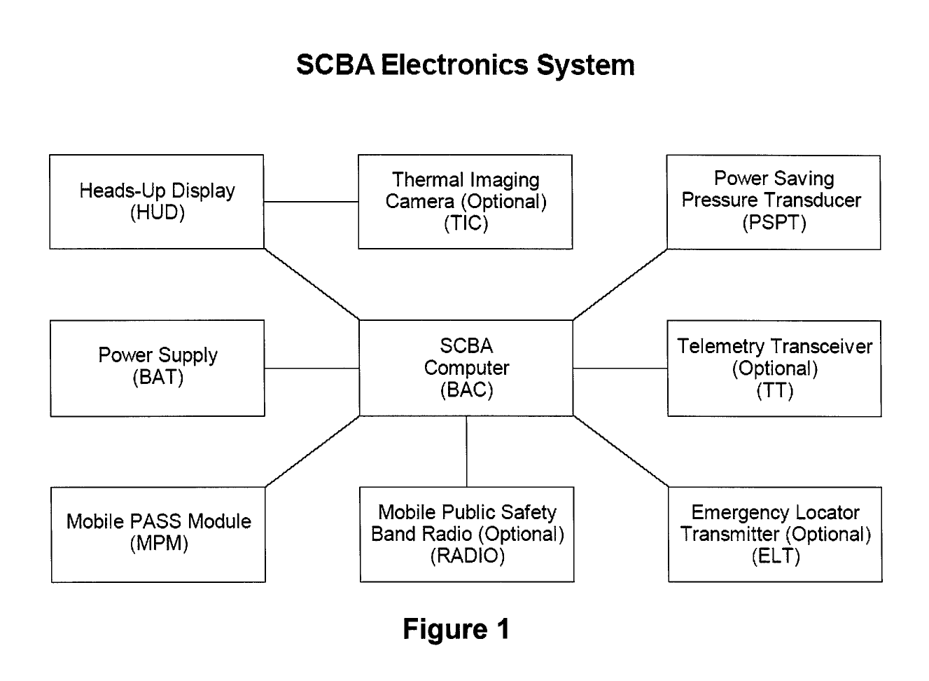

The instant invention 100 is comprised of a portable, battery operated SCBA electronics system designed for use by firefighters and other emergency personnel. The SCBA electronics system is used to provide breathing air to personnel operating in harsh environmental conditions. Its primary functions include; providing the operator with an indicator of the amount of breathing air in the SCBA's air tank, monitoring the movement of the operator and emitting an alert if the operator goes without motion for a specified time, logging of alert conditions and ambient environmental conditions during operation, providing visual and audio indicators during operation to allow easier tracking of the SCBA in visually obscured environments, and amplifying the operator's voice to facilitate communications while the operator is using breathing air. The SCBA system includes the following modules, as shown in FIG. 1, a Main SCBA Computer Module (BAC), Mobile Personal Alert Safety System (PASS) Module (MPM), Power Saving Pressure Transducer (PSPT) Module, Heads-Up Display (HUD) Module, Power Supply Module (BAT), Thermal Imaging Camera (TIC), Emergency Locator Transmitter (ELT) Module, Mobile Public Safety Band Radio (RADIO) Module, and Telemetry Transceiver (IT) Module, each of which is described in greater detail.

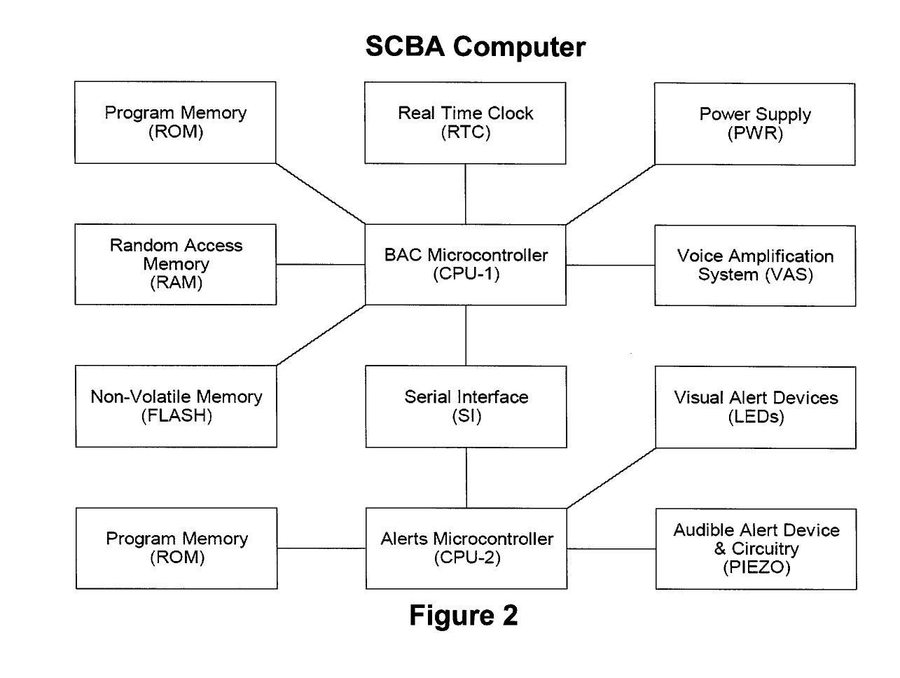

The Main SCBA Computer Module (BAC) is the main control module for the SCBA system. It receives power from the Power Supply Module (BAT) and interfaces to the other modules in the system. The Power Supply Module (BAT) contains the system batteries. It connects to the BAC module through a power supply cable. It contains power protection circuitry to allow the SCBA electronics to comply with UL 913, 6th edition. The primary components for the BAC module are shown in FIG. 2. This module is responsible for the following functions: supplying power to the other modules (PWR), monitoring the system battery voltage, logging of events that occur during operation into the flash Memory, maintaining a real time clock (RTC) to provide a time stamp for logged events, reading current system pressure from the PSPT through a serial interface, sending pressure readings and alerts messages to the HUD display through a serial interface, communicating with the MPM through a serial interface, sounding audible system alerts through the Alerts Microcontroller, illuminating visual system alerts, controlling activation of the Emergency Locator Transmitter (ELT) Module, communicating with the Telemetry Transmitter (TT) module through a serial interface, routing voice audio from the HUD Display microphone to the Voice Amplification System (VAS), routing voice audio from the HUD Display microphone to the RADIO module, routing audio from the VAS to the MPM speaker and routing audio from the RADIO module to the Voice Amplifier.

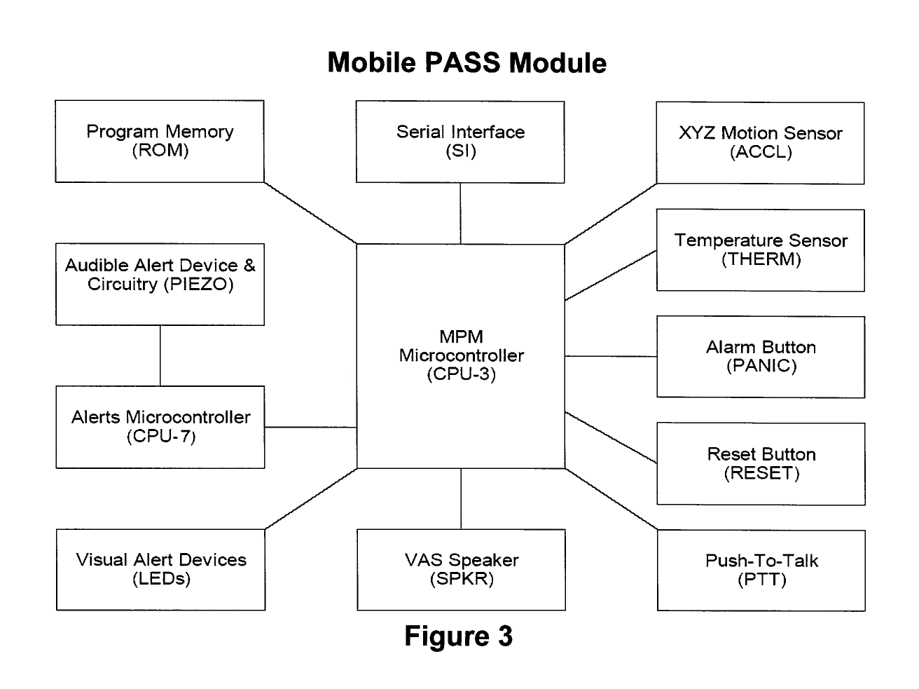

As shown in FIG. 3, the Mobile Personal Alert Safety System (PASS) Module (MPM) provides an interface to the operator for controlling the operations of the SCBA system, including, but not limited to, activating the system using the PANIC button, resetting the system using the RESET button and routing of the voice audio of the Voice Amplification System (VAS) using the Push to Talk (PTT) button. The MPM module also detects motion during operation, monitors ambient temperature, sounds audible system alerts through the Alerts Microcontroller, and illuminates visual system alerts. The MPM houses the speaker for the VAS and it communicates with the BAC module through a serial interface.

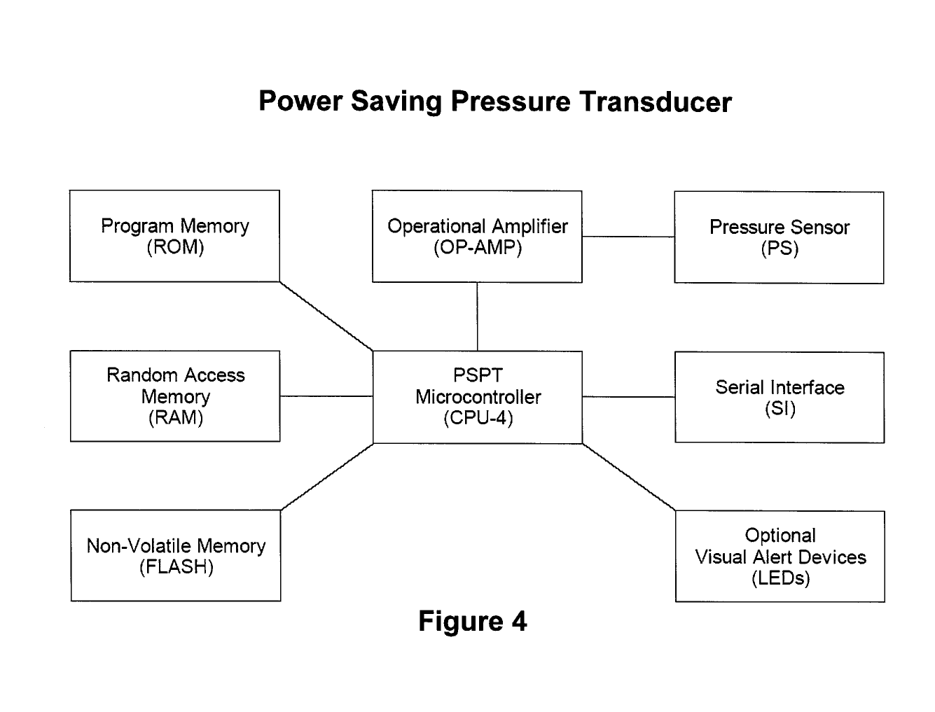

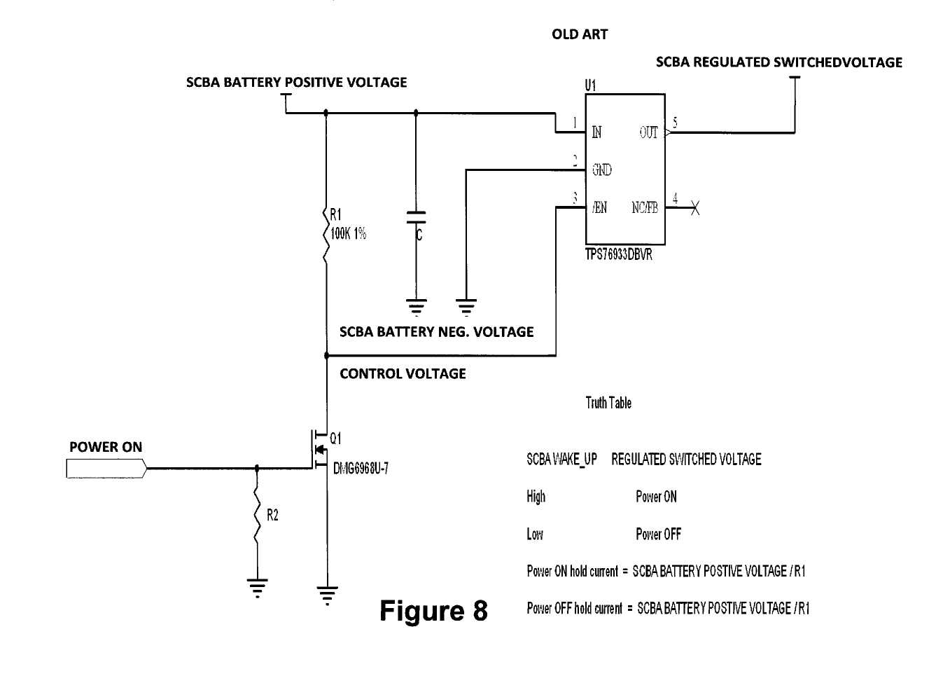

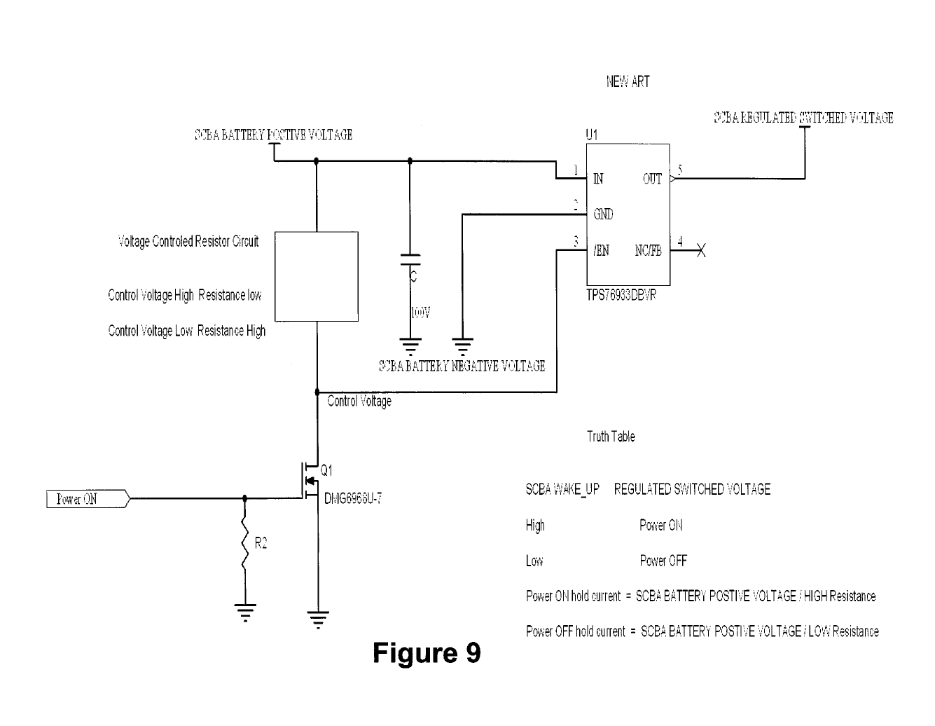

As shown in FIG. 4, the Power Saving Pressure Transducer (PSPT) Module monitors the SCBA air pressure. It is required to continuously monitor the system pressure, even when the system is inactive, so it is always under power. It communicates with the BAC module through a serial interface. In order to maximize battery life the PSPT utilizes a low power sleep mode to conserve battery life. Specifically, a high current regulator for Active Mode operation and a low quiescent current regulator for Inactive (Sleep) Mode operation. The most common EMI resistance circuit methods employs shielding, low source impedance and protection devices to mitigate the effects of EMI, as shown in FIG. 8. The disadvantage of the low source impedance technique is that the amount of power required in protecting the circuit increases with protection levels. The lower the impedance of the circuit the greater the EMI protection level and power consumed. The instant invention provides a power conserving EMI Circuit that changes the impedance of the circuit from a low impedance high protection when the SCBA electronics is in Sleep Mode to high impedance low power when in Active Mode to save battery power, shown in FIG. 9. Thus when the SCBA is in Sleep Mode the impedance is low for EMI resistance and when the SCBA is in Active Mode the impedance is high for power saving purposes. The low quiescent current regulator is used to power only the SCBA components that are required for Sleep Mode operation, which includes the PSPT Module which monitors the air tank pressure and the RTC continuously. When the PSPT detects air tank pressure above the NFPA specified level, it forces the SCBA system to become active by switching on the high current voltage regulator. The PSPT conserves power by operating in a low power mode the majority of the time. An internal clock that runs in the PSPT during Sleep Mode periodically ‘wakes up’ the PSPT Module to allow it to perform an Air Tank pressure measurement.

Additionally, the PSPT Module employs a piezo-resistive pressure sensor to measure the pressure of the SCBA breathable air during operation. The pressure sensor is in direct contact with the breathable air (open circuit). Prior art SCBA manufacturers utilize a closed system with an oil filled sensor chamber sealed with a thin metal diaphragm. The disadvantage of the closed system is that under high temperature the enclosed oil can expand and create an artificially high pressure reading, and under extreme temperature conditions the metal diaphragm can rupture. The instant invention employs an open circuit measurement system in the PSPT. Therefore, temperature issues associated with the closed systems do no exist, but moisture in the breathable air could possibly come into direct contact with the pressure sensor and affect the pressure reading. The PSPT utilizes an open circuit pressure measurement design featuring a capillary tube that prevents water from entering the chamber containing the pressure sensor, allows the breathable air to come into direct contact with the pressure sensor, and gives good pressure measurement performance over a wider temperature range than a closed circuit system. The PSPT utilizes a 0.15″ diameter capillary tube (the opening is sufficiently small in diameter to prevent water from entering in to the pressure sensor chamber) at the opening of the chamber containing the pressure sensor to block water from entering the chamber but allowing the breathable air to pass unobstructed.

However, the piezo-resistive pressure sensor is susceptible to EMI and RFI noise. When a voltage is applied to the pressure sensor it outputs a voltage that it proportional to the applied pressure. The output voltage from the pressure sensor is then amplified, utilizing op amps, to give a higher voltage level for more accurate measurement. The amplified signal from the op amps is very sensitive to EMI or RFI noise in the environment because any outside noise is also amplified. When the SCBA is inactive, the PSPT is constantly monitoring the breathable air pressure. When the air pressure rises above a specified level, the PSPT will awaken the SCBA electronics. In a system without any filtering of EMI or RFI noise, a large noise spike could be interpreted as pressure and cause the SCBA electronics to wake-up inadvertently. The EMI and RFI noise usually manifests as a short spike in pressure which could be filtered out using a firmware algorithm. The algorithm checks for a constantly increasing air pressure over a period of time to verify that the pressure is valid prior to waking up the SCBA electronics.

The Modules that comprise the SCBA Electronics System are required to communicate with each other reliably in harsh environments that include temperature extremes and high levels of RFI and EMI. Prior art devices commonly implemented communication schemes using single line serial communications that were more susceptible to errors due to interferences. To insure reliable communications the instant invention utilizes a derivative of the IEEE RS-485 communications bus the circuit design for communication between the various SCBA Electronics Modules. Specifically, the RS-485 bus circuit design is implemented for error detection due to interference.

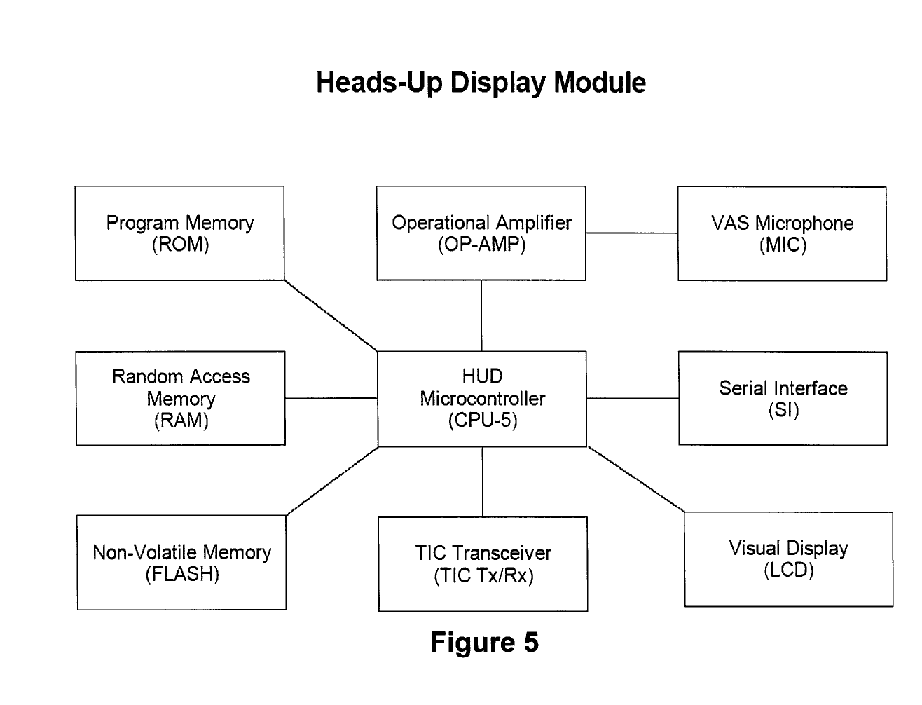

As shown in FIG. 5, the Heads-Up Display (HUD) Module provides a visual indication of the SCBA air pressure and a visual indication of SCBA electronics system alerts. It also contains a microphone to provide voice audio to the VAS in the BAC module and interface for a non NFPA mandated Thermal Imaging Camera (TIC). It communicates with the BAC module through a serial interface.

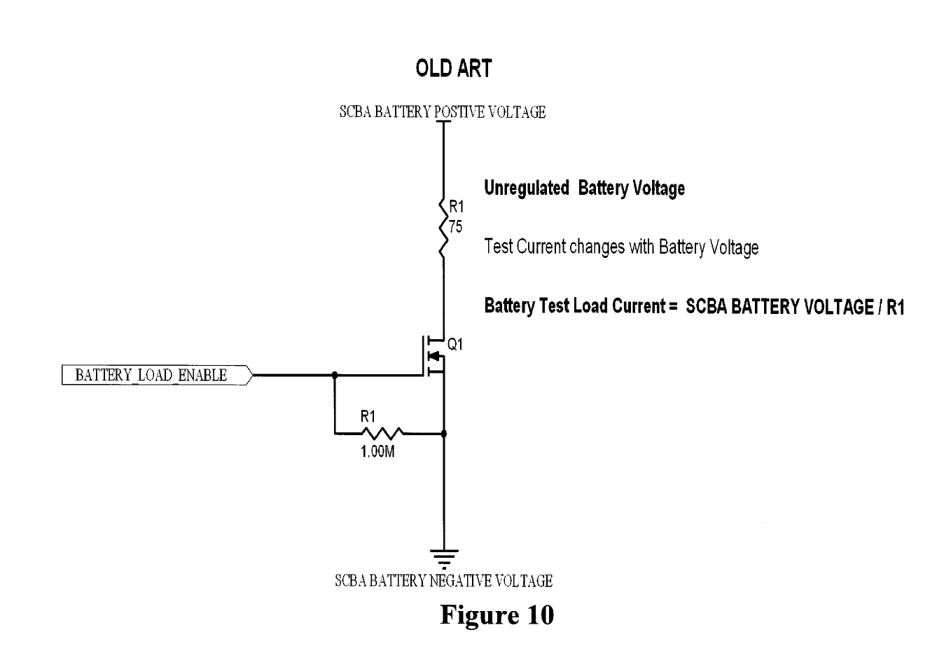

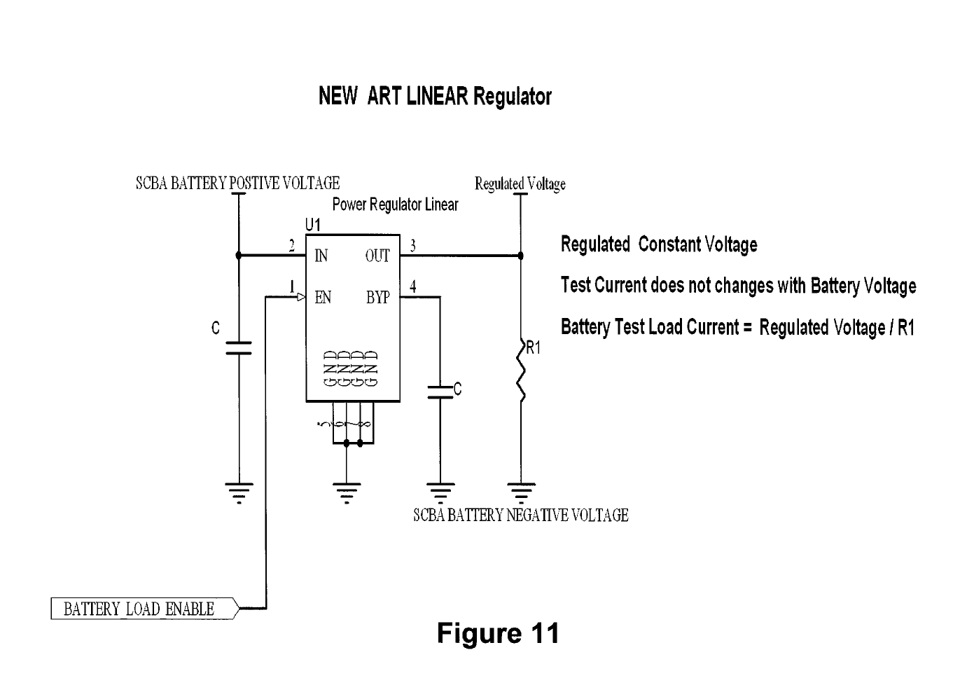

In the instant invention a method for conserving battery power in SCBA Electronics Systems during battery load testing is provided. As shown in FIG. 10, the prior art uses a common battery test load method which employs a fixed resistor value switched across the battery as a temporary load. The voltage across the battery is monitored during the load test. As the battery capacity decreases the battery voltage also decreases. The battery test load current is a function of OHM's law (Current=Voltage/Resistance). As the battery voltage decreases due to discharge the battery test load current also decreases. The ohm value of the battery test load resistor must be selected to guarantee that the low battery voltage load is similar to the actual SCBA load using ohm law. This causes the battery test load current at high battery voltage levels to be unnecessary excessive, decreasing battery life. The instant invention provides a system that employs a voltage regulator and a fixed battery load resistor, shown in FIG. 11. The voltage regulator provides a fixed voltage across the battery load resistor to perform a SCBA battery health check. The voltage regulator can be any circuit that provides a fixed voltage across the battery test load resistor. Thereby the system conserves battery power at high battery voltage during the SCBA health check when the battery is placed under load. Additionally, a low leakage solid state transistor is provided to switch the battery power to the voltage regulator on and off.

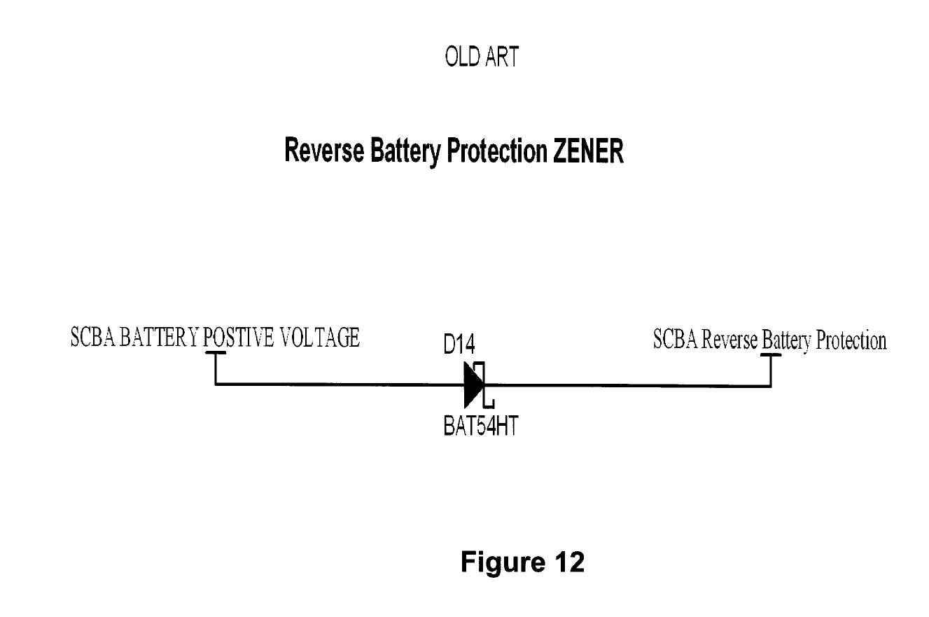

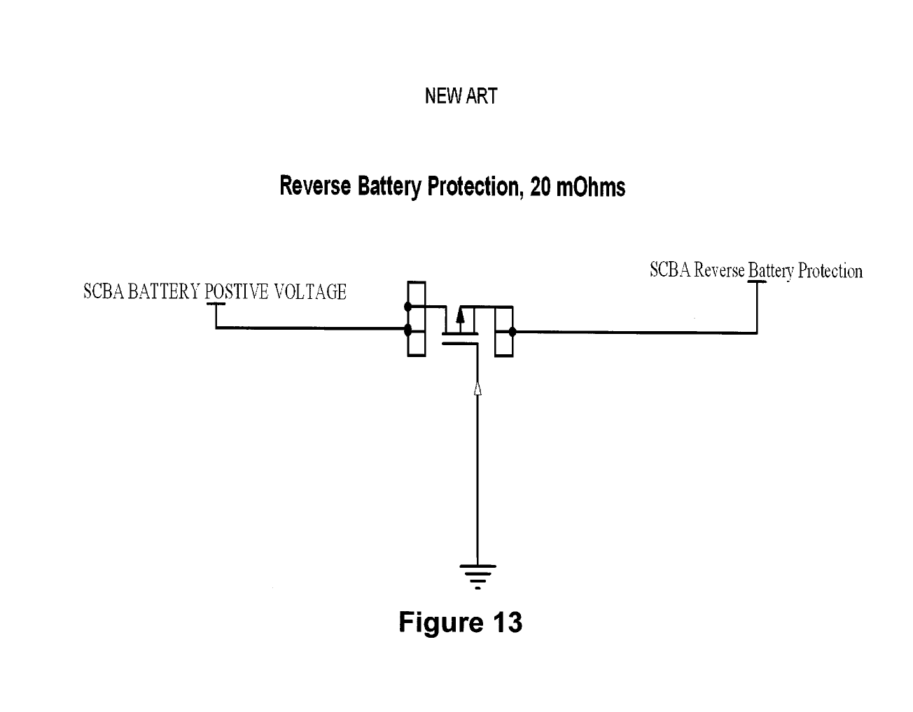

Furthermore, when the batteries are changed in a SCBA system may be mistakenly put in backwards. The common method of blocking reverse batteries is with a Schottky Diodes forward bias placed in series with the battery power path. The Schottky Diode Reverse battery protection has an inherent forward voltage drop which causes power loss. As shown in FIG. 12, by connecting a p-channel MOSFET in the positive supply line of the load, reverse battery protection is achieved. By referring the Gate signal to the ground line, the SCBA system is fully turned on when the battery is applied in the right polarity. For the first start up, the intrinsic body diode of the MOSFET will conduct, until the channel is switched on in parallel. By reverse polarity, the MOSFET will be switched off, because the Gate Source voltage for this case will be positive, as shown in FIG. 13.

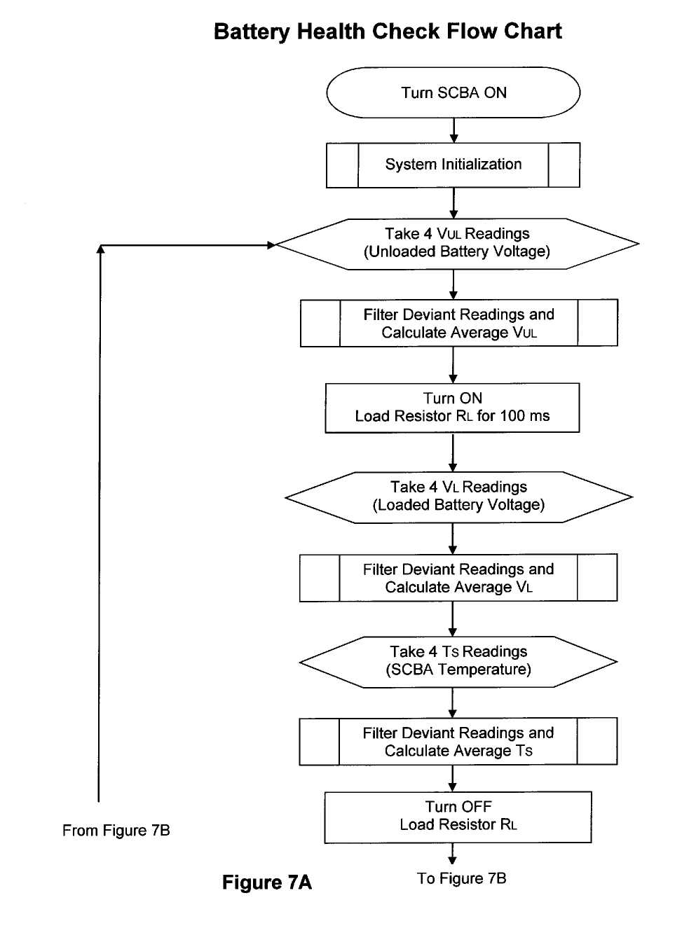

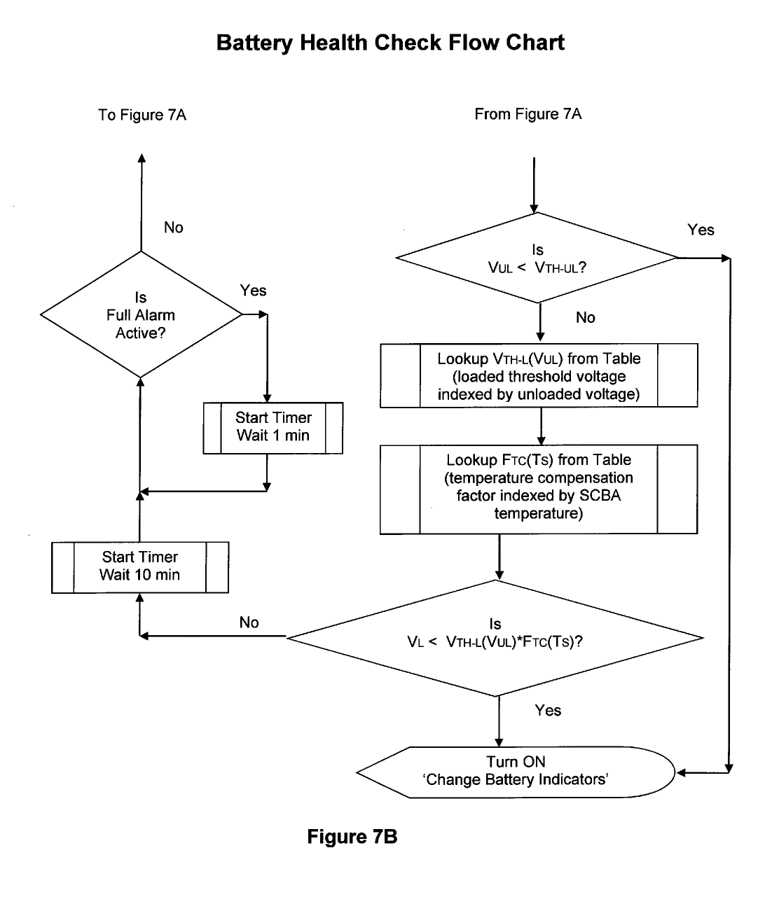

As shown in FIGS. 7A-7B, a method for determining battery condition and estimating remaining battery life is provided. The method includes measuring a voltage on the batteries, whereby the voltage is measured in an unloaded state (VUL) and a loaded state (VL) using a temporary load that is proportional to the estimated maximum load of said electronics system. An unloaded voltage threshold level (VTH-UL) and a loaded voltage threshold level (VTH-L) can thereafter be determined empirically through measurement of the voltage decrease in SCBA's batteries during operation over time. Additionally one can then compare the unloaded (VUL) state measurement with the unloaded voltage threshold level (VTH-UL) and the loaded state voltage (VL) measurement to the loaded voltage threshold level (VTH-L). If the unloaded (VUL) state measurement is less than said unloaded voltage threshold level (VTH-UL) a change battery indicator will be activated. Additionally, the method will further include monitoring the ambient temperature so that a temperature compensation value can be applied to the threshold levels to compensate for the variation in the electronics system's load with a temperature change. Thereafter if the loaded state voltage (VL) measurement is less than the unloaded voltage threshold level (VTH-UL) having the temperature compensation value then activate the change battery indicator. The system will continuously monitor the voltage across the SCBA's batteries when the loaded (VUL) state measurement is not less than the unloaded voltage threshold level (VTH-UL) or when the loaded state voltage (VL) measurement is not less than the unloaded voltage threshold level (VTH-UL) having the temperature compensation value.

The NFPA requires that a Personal Alert Safety System (PASS) device enters Pre-Alarm Mode if a firefighter is detected to be motionless for 20 seconds. The PASS piezo emitter must generate an NFPA specified sound in Pre-Alarm Mode. If the firefighter continues to remain motionless for an additional 12 seconds, the PASS must enter Alarm Mode and generate an NFPA specified alarm sound continuously thereafter, unless the PASS piezo is turned OFF by depressing the Reset button. Most SCBA manufacturers equip their PASS devices with an accelerometer to detect motion. Some SCBA manufacturers also include a piezo emitter and/or a VAS speaker in their PASS device housing. In prior art devices, a problem/safety issue can occur when, under certain circumstances, vibrations generated by the piezo or speaker are transmitted through the PASS device housing and cause interference with the operation of the accelerometer. Specifically, this can happen when the piezo commences emitting sound, which causes vibrations, which are then transmitted through the housing to be detected by the accelerometer, which then sends a signal to the Microcontroller that it is detecting vibrations. The Microcontroller interprets the vibrations as movement by the firefighter, turns OFF the piezo and resets the 20-second clock. This can result in a safety issue because the PASS will never enter Alarm Mode even if the firefighter is unconscious or otherwise incapacitated and not moving.

The instant invention provides an accelerometer that needs only to detect low frequency motion for proper operation, as the vibration caused by the piezo emitter and/or VAS speaker has been determined to be primarily at higher frequency. Therein, a software algorithm is implemented in the Mobile PASS Module to attenuate high frequency vibrations, allowing low frequency motion to be detected with less interference. Additionally, the algorithm is further tuned separately for each axis of movement on the XYZ accelerometer.

The NFPA requires ‘Black Box’ data-logging for SCBA's. Thus the SCBA electronics must record and time-stamp alarm conditions and certain specified events. The data logs provide forensic information in the event of an accident during the operation of the SCBA. The RTC is used to provide the time-stamp and it is imperative that the time-stamp is accurate for forensic purposes. However, should there be an RTC failure, the time-stamp would be lost, thereby rendering the logged data useless for forensic purposes. When an RTC failure occurs, it results in the time-stamp date reverting to the RTC default date, which is typically set when the SCBA is powered for the first time. In the instant invention, upon first power up a backup time stamp is initialized and maintained by the system clock—the Microcontroller's internal oscillator (which is separate from the RTC clock); additionally a default date/time is selected for the RTC clock. Upon each subsequent power up the Microcontroller polls the RTC for the current date/time and compares the date/time provided by the RTC to the most recent time-stamp from the most recently stored data log. If the Microcontroller determines that the RTC has provided an unrealistic or invalid date/time, indicative of RTC failure, then the backup time-stamp is used henceforth in its place.

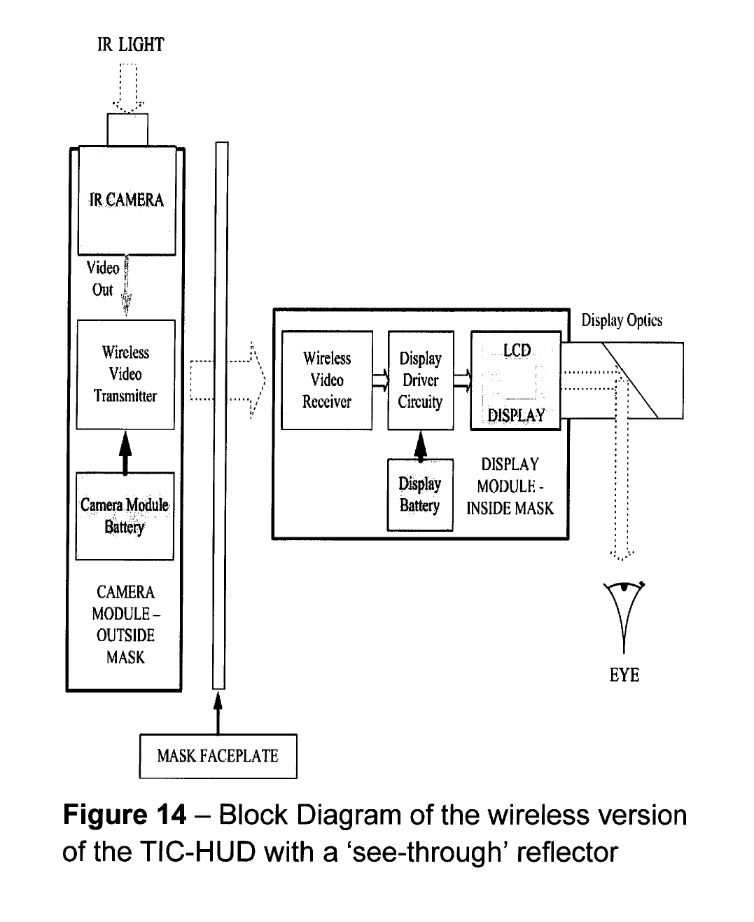

The Thermal Imaging Camera (TIC) is a non NFPA mandated component. It interfaces with the HUD modules and uses the HUD display to provide a thermal image of the surrounding operating environment. FIG. 14 depicts a wireless version of the TIC-HUD see through reflector. This arrangement includes an external TIC module mounted on the side of the SCBA facemask and an independently powered HUD module, mounted inside the SCBA facemask. The HUD module would be mounted inside the facemask, in a position visible to the operator, such as over the bridge of the operator's nose. The video from the TIC module would be transferred wirelessly by radio frequency or optical signal to the HUD module inside the mask. The HUD optics would include a lens with the field of view (FOV) and the magnification factor adjusted to allow for a 1:1 scale display of the visible scene. A transparent reflector, such as an electrically switchable LCD reflector, would be attached to the HUD and positioned over the operator's eye. The operator would view the visible scene through this reflector when the HUD is not in use.

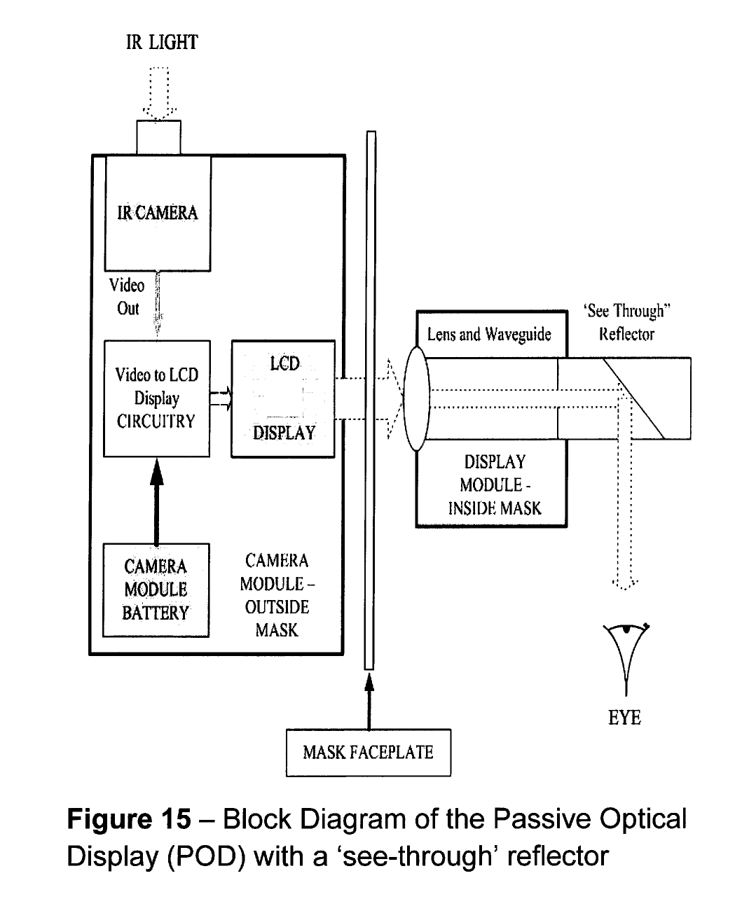

Referring to FIG. 15, a passive optical display (POD) may be mounted inside the facemask. This design option would include an external TIC module mounted on the side of the SCBA facemask incorporating an LCD display and a purely passive optical display (POD) mounted inside the SCBA facemask incorporating an optical waveguide and lens. The advantage of this design is that it would eliminate all the inside mask electronics, batteries, video transport, active displays panels and hardware mounts that are needed to support the inside mask electronics. The video image from the TIC module would be generated on the LCD incorporated into the module housing on the outside of the facemask and transmitted directly thru the clear mask faceplate. The video image would then be acquired inside the facemask by the POD using lens mated to an optical waveguide/light pipe. The POD would then reflect the image into the operator's eye using a ‘see-through’ dual prismatic reflector. The prismatic reflector would be positioned over the operator's eye so that the operator would be able view the visible scene through this reflector when the TIC display is off. The magnification factor of the POD optics would be designed to allow for a 1:1 scale display of the visible scene. The brightness of the image displayed on the POD would be adjustable through adjustment of the backlight brightness of the LCD display incorporated in the external TIC housing. The brightness adjustment could be done automatically by incorporating ambient light detection circuitry into the external TIC housing.

The Emergency Locator Transmitter (ELT) Module is a non NFPA mandated component. When activated, it emits a signal that can be tracked using a matching tracking system. It is controlled directly by the BAC module.

The Mobile Public Safety Band Radio (RADIO) Module is a non NFPA mandated component. It provides an interface to an external radio. When the radio is connected, audio from the radio is routed to the VAS speaker in the MPM, voice audio from the HUD microphone is routed to the radio transmitter and the PTT button in the MPM is used to control the radio transmitter.

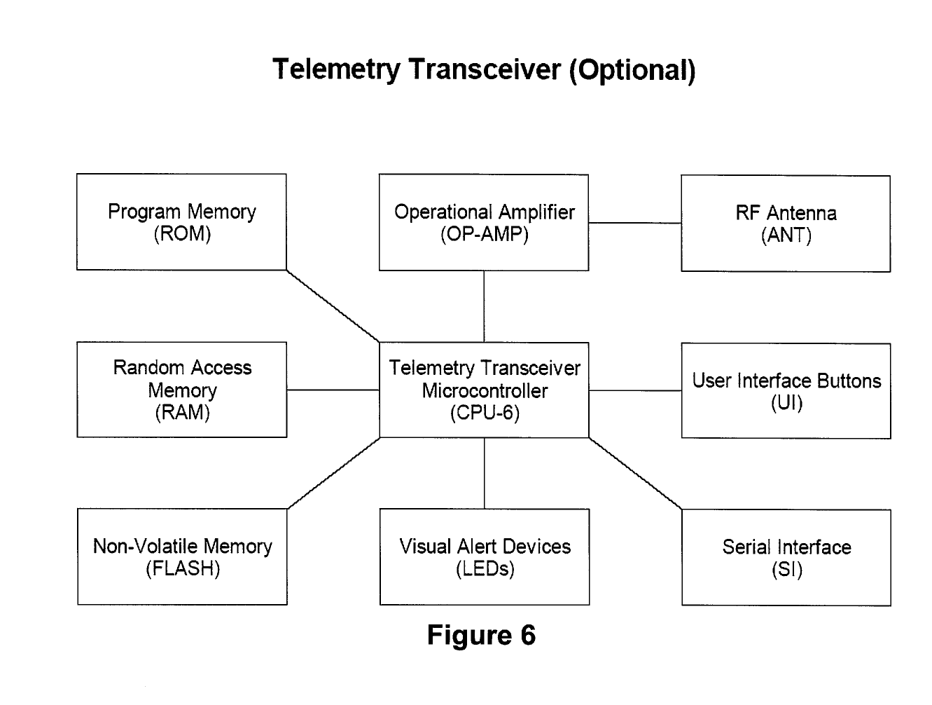

Telemetry Transceiver (TT) Module is a non NFPA mandated component. It contains a radio transceiver and RF antenna that are used to relay telemetry data between the SCBA electronics and a remote base station during operation. It contains visual indicators to show the telemetry system status. It communicates with the BAC module through a serial interface. The primary components of this module are shown in FIG. 6.

All patents and publications mentioned in this specification are indicative of the levels of those skilled in the art to which the invention pertains. All patents and publications are herein incorporated by reference to the same extent as if each individual publication was specifically and individually indicated to be incorporated by reference.

It is to be understood that while a certain form of the invention is illustrated, it is not to be limited to the specific form or arrangement herein described and shown. It will be apparent to those skilled in the art that various changes may be made without departing from the scope of the invention and the invention is not to be considered limited to what is shown and described in the specification and any drawings/figures included herein.

One skilled in the art will readily appreciate that the present invention is well adapted to carry out the objectives and obtain the ends and advantages mentioned, as well as those inherent therein. The embodiments, methods, procedures and techniques described herein are presently representative of the preferred embodiments, are intended to be exemplary and are not intended as limitations on the scope. Changes therein and other uses will occur to those skilled in the art which are encompassed within the spirit of the invention and are defined by the scope of the appended claims. Although the invention has been described in connection with specific preferred embodiments, it should be understood that the invention as claimed should not be unduly limited to such specific embodiments. Indeed, various modifications of the described modes for carrying out the invention which are obvious to those skilled in the art are intended to be within the scope of the following claims.

What is claimed is:

1. A method of improving a self contained breathing apparatus (SCBA) electronics system comprising the steps of:
coupling an electronics system means with a real time clock (RTC) with a high current regulator to allow for Active Mode operation and a low quiescent current regulator to allow for Inactive (Sleep) Mode operation, said Inactive Mode electrically coupled to a Power Saving Pressure Transducer (PSPT) Module to monitor air tank pressure; and
utilizing a power conserving electromagnetic interference (EMI) circuit to change circuit impedance when said electronics system means is in said Inactive Mode to a high impedance low power when in said Active Mode to save battery power.

2. The method improving an SCBA according to claim 1 further comprising the step of performing a periodic air tank pressure measurement check during said Inactive Mode using said RTC as a timer.

3. The method improving an SCBA according to claim 1 whereby said PSPT includes a piezo-resistive pressure sensor operatively associated with said electronic system means employing a firmware algorithm for constantly checking for an increase in air pressure to verify that said increase in air pressure is not due to EMI or RFI interference prior to switching to said Active Mode.

4. The method improving an SCBA according to claim 1 including the step of:
measuring voltage of the SCBA electronic system means batteries in both an unloaded state and a loaded state using a temporary load that is proportional to the estimated maximum load of said electronics system;
determining an unloaded voltage threshold level (VTH-UL) and a loaded voltage threshold level (VTH-L) empirically through measurement of a decrease in said voltage in said SCBA electronic system means batteries during operation over time,
comparing said unloaded (VUL) state measurement with said unloaded voltage threshold level (VTH-UL) and said loaded state voltage (VL) measurement to said loaded voltage threshold level (VTH-L), and
activating a battery change indicator when said unloaded (VUL) state measurement is less than said unloaded voltage threshold level (VTH-UL).

5. The method improving an SCBA according to claim 4 including the step of monitoring ambient temperature so that a temperature compensation value can be applied to said threshold levels to compensate for the variation in said electronics system load in the case of a temperature change.

6. The method improving an SCBA according to claim 5 further comprising the step of activating said battery change indicator when said loaded state voltage (VL) measurement is less than said unloaded voltage threshold level (VTH-UL) having applied said temperature compensation value.

7. The method improving an SCBA according to claim 6 including the step of continuously monitoring said voltage across said self contained breathing apparatus electronics system's batteries when said loaded (VUL) state measurement is not less than said unloaded voltage threshold level (VTH-UL) or when said loaded state voltage (VL) measurement is not less than said unloaded voltage threshold level (VTH-UL) having applied said temperature compensation value.

8. The method improving an SCBA according to claim 1 including the step of maintaining a reliable time-stamp in said electronics system means by:
entering a date and time on a system clock upon start up, said system clock being a part of a SCBA electronics system having an internal oscillator;
entering a default date and time for said real time clock;
comparing said time and date provided by said real time clock and the most recent said time and date by said system clock;
determining if said real time clock provided an invalid said time and date, indicative of said real time clock experiencing a failure; and
using said system clock's said time and date henceforth.

9. The method improving an SCBA according to claim 4 including the step of employing a voltage regulator and a fixed battery load resistor; said voltage regulator provides a fixed voltage across said battery load resistor to perform a SCBA battery health check; and
conserving battery power at high battery voltage during said SCBA health check when said battery is placed under load.

10. The method improving an SCBA according to claim 9 including the step of employing a low leakage solid state transistor to switch the battery power to said voltage regulator.

11. The method improving an SCBA according to claim 1 further comprising the step of connecting a p-channel metal oxide semiconductor field effect transistor (MOSFET) in the positive supply line of the load to give a reverse battery protection and to minimize the voltage drop through the reverse battery protection circuitry.

12. The method improving an SCBA according to claim 1 including the steps of:
positioning an accelerometer in a Personal Alert Safety System Module to detect low frequency motion and high frequency vibration;
employing an algorithm to attenuate high frequency vibrations and allowing low frequency motion to minimize piezo and voice amplification system speaker interference in a motion detection circuit in the Personal Alert Safety Module;
tuning said algorithm for each axis of movement on said accelerometer; and
mechanically decoupling said accelerometer from said piezo and said voice amplification system speaker by a rubber gasket.

13. A method improving an SCBA comprising the steps of:
attaching an electronics system means to an accelerometer in a Personal Alert Safety System Module to detect low frequency motion and high frequency vibration;
employing an algorithm to attenuate high frequency vibrations and allowing low frequency motion to minimize piezo and voice amplification system speaker interference in a motion detection circuit in the Personal Alert Safety Module;
tuning said algorithm for each axis of movement on said accelerometer; and
mechanically decoupling said accelerometer from said piezo and said voice amplification system speaker by a rubber gasket.

14. The method of improving an SCBA according to claim 13 including the steps of:
coupling said electronics system means to a real time clock (RTC) with a high current regulator to allow for Active Mode operation and a low quiescent current regulator to allow for Inactive (Sleep) Mode operation, said Inactive Mode electrically coupled to a Power Saving Pressure Transducer (PSPT) Module to monitor air tank pressure; and
utilizing a power conserving electromagnetic interference (EMI) circuit to change circuit impedance when said electronics system means is in said Inactive Mode to a high impedance low power when in said Active Mode to save battery power.

15. The method improving an SCBA according to claim 14 including the step of performing a periodic air tank pressure measurement check during said Inactive Mode using said RTC as a timer.

16. The method improving an SCBA according to claim 14 whereby said PSPT includes a piezo-resistive pressure sensor operatively associated with said electronic system means employing a firmware algorithm for constantly checking for an increase in air pressure to verify that said increase in air pressure is not due to EMI or RFI interference prior to switching to said Active Mode.

17. The method improving an SCBA according to claim 13 including the step of:
measuring voltage of the SCBA electronic system means batteries in both an unloaded state and a loaded state using a temporary load that is proportional to the estimated maximum load of said electronics system;
determining an unloaded voltage threshold level (VTH-UL) and a loaded voltage threshold level (VTH-L) empirically through measurement of a decrease in said voltage in said SCBA electronic system means batteries during operation over time,
comparing said unloaded (VUL) state measurement with said unloaded voltage threshold level (VTH-UL) and said loaded state voltage (VL) measurement to said loaded voltage threshold level (VTH-L), and
activating a battery change indicator when said unloaded (VUL) state measurement is less than said unloaded voltage threshold level (VTH-UL).

18. The method improving an SCBA according to claim 17 including the step of monitoring ambient temperature so that a temperature compensation value can be applied to said threshold levels to compensate for the variation in said electronics system load in the case of a temperature change.

19. The method improving an SCBA according to claim 17 further comprising the step of activating said battery change indicator when said loaded state voltage (VL) measurement is less than said unloaded voltage threshold level (VTH-UL) having applied said temperature compensation value.

20. The method improving an SCBA according to claim 17 including the step of continuously monitoring said voltage across said self contained breathing apparatus electronics system's batteries when said loaded (VUL) state measurement is not less than said unloaded voltage threshold level (VTH-UL) or when said loaded state voltage (VL) measurement is not less than said unloaded voltage threshold level (VTH-UL) having applied said temperature compensation value.

21. The method improving an SCBA according to claim 13 including the step of maintaining a reliable time-stamp in said electronics system means by:
entering a date and time on a system clock upon start up, said system clock being a part of a SCBA electronics system having an internal oscillator;
entering a default date and time for said real time clock;
comparing said time and date provided by said real time clock and the most recent said time and date by said system clock;
determining if said real time clock provided an invalid said time and date, indicative of said real time clock experiencing a failure; and
using said system clock's said time and date henceforth.

22. The method improving an SCBA according to claim 13 including the step of employing a voltage regulator and a fixed battery load resistor; said voltage regulator provides a fixed voltage across a battery load resistor to perform a SCBA battery health check; and
conserving battery power at high battery voltage during said SCBA health check when said battery is placed under load.

23. The method improving an SCBA according to claim 22 including the step of employing a low leakage solid state transistor to switch the battery power to said voltage regulator.

24. The method improving an SCBA according to claim 17 further comprising the step of connecting a p-channel metal oxide semiconductor field effect transistor (MOSFET) in the positive supply line of the load to give a reverse battery protection and to minimize the voltage drop through the reverse battery protection circuitry.

25. A method improving an SCBA comprising the steps of:
positioning an external TIC module on the side of a SCBA facemask;
positioning a display module inside the SCBA facemask;
transferring images from said TIC module to said display module; wherein said display module includes optics with a field of view magnification factor to allow for a 1:1 scale display of a visible scene.

26. The method improving an SCBA according to claim 25 including a transparent reflector to allow viewing of said images without directly viewing the HUD.

27. The method improving an SCBA according to claim 26 wherein said transparent reflector is an electrically switchable LCD.

28. The method improving an SCBA according to claim 25 wherein said images are transferred by radio frequency.

29. The method improving an SCBA according to claim 25 wherein said images are transferred by optical signal.

30. The method improving an SCBA according to claim 25 wherein said display module is an independently powered HUD.

31. The method improving an SCBA according to claim 25 wherein said display module is a POD, and the image from the TIC module is transmitted thru the mask faceplate and acquired inside the facemask by the POD using a lens mated to an optical waveguide/light pipe for viewing on a prismatic reflector.

32. The method improving an SCBA according to claim 31 wherein the brightness of the image displayed on the POD is adjustable by incorporating ambient light detection circuitry into the external TIC housing.
